(19) United States
(12) Patent Application Publication
(10) Pub. No.: US 2010/0224242 A1
(43) Pub. Date: Sep. 9, 2010

(54) PHOTOELECTRIC CONVERTING DEVICE AND METHOD FOR FABRICATING THE SAME

(75) Inventors: You-Chia Chang, Taichung City (TW); Chun-Ti Chen, Hsinchu City (TW); Jen-You Chu, Changhua County (TW); Yu-Hsin Yeh, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/466,379

(22) Filed: May 14, 2009

(30) Foreign Application Priority Data
Mar. 4, 2009 (TW) 98106997

(51) Int. Cl. H01L 31/0236

(52) U.S. Cl. 136/256; 438/57; 257/E31.13

(57) ABSTRACT

A photoelectric converting device which includes a substrate layer and an active layer is proposed. The active layer, which is disposed over the substrate layer, has a light receiving surface with a textured structure. The textured structure includes multiple indented units and each of the indented units includes three planes, which form an indentation tip at the intersection point between the three planes. The three planes are perpendicular or about perpendicular to each other.

### CROSS-REFERENCE TO RELATED APPLICATION

This application claims the priority benefit of Taiwan application serial no. 98106997, filed on Mar. 4, 2009. The entirety of the above-mentioned patent application is hereby incorporated by reference herein and made a part of specification.

### BACKGROUND OF THE INVENTION

1. Field of Invention

The present invention relates to photoelectric converting device with high optical coupling efficiency.

2. Description of Related Art

Solar energy has been gradually used to replace the conventional energy source, such as petroleum. However, if the whole solar cell is fabricated with semiconductor material, it would cause seriously short for the material to form the substrate and the price would increase. Another choice for the solar cell is taking the glass substrate or ceramic substrate at lower price, and then a thin solar cell is coated thereon. Since the substrate of this solar cell has no specific limitation and can be conveniently form on different material, it is very promising.

The ceramic substrate has properties of low price and it can endure high temperature and poor environment. In addition, the ceramic itself is formed by sintering the ceramic powder, and therefore it is a very good Lambertian reflector. When the sunlight is incident onto that surface, the reflection light would be uniformly diffused. If it is taken as the substrate of the thin film solar cell, it would effectively diffuse the incident light and thus the light being directly reflected back is reduced. When the diffused light propagates inside the thin film, it can effectively trapped inside the thin film and be absorbed by the material. Therefore, this material is good for serving as the substrate of the solar cell.

The ceramic substrate can be used for various coating materials, such as amorphous silicon, polysilicon, crystalline silicon, silicon/germanium, III-V or II-VI (CdTe) semiconductor, small molecule, polymer, dye sensitized material, or copper indium gallium selenide (CIGS). However, although solar cells can adopt the form of thin film to save the cost, the thin film layer is too thin and the light absorption is far less than that adopting the form of bulk material. In addition, the material has rather high reflection for the visible light and near infrared. The reflection loss at the interface is rather serious. To solve this problem, good methods for light-in coupling and light trapping are needed, so as to couple the sunlight into the thin film and increase the optical path inside the thin film by structure design. Then, the performance of the thin film solar cell can be greatly improved.

FIG. 1 is a drawing which schematically illustrates the light reflection at the flat surface. In FIG. 1, bulk silicon (Si) with a smooth surface is taken as an example. When the light is vertically incident on the surface, some of it is reflected, as shown by arrows. The interface between silicon and the air would cause reflection loss by about 33%.

FIG. 2 is a drawing which schematically illustrates the light reflection of the inverted pyramid texture. This texture design is conventionally used for high-efficiency single-crystal silicon solar cells. Most of the vertically-incident light reflects twice before the light leaves the silicon substrate, and therefore reflection loss is reduced. Multiple reflections allow light to impinge on the surface again, increasing the chance to enter the silicon layer. After two-time reflections, the reflection loss can be reduced down to 11%.

How to properly design the structure to increase the efficiency for the thin film solar cell, based on ceramic substrate in fabrication, is an issue to be considered in the art for developing.

### SUMMARY OF THE INVENTION

The invention provides a photoelectric converting device and the fabrication method. The reflection loss can be at least reduced.

In an aspect, the invention provides a photoelectric converting device, including a substrate layer and an active layer. The active layer is disposed over the substrate layer. The active layer has a light receiving surface with a textured structure. The textured structure includes multiple indented units and each of the indented units includes three planes, which form an indentation tip at the intersection point between the three planes. The three planes are perpendicular or about perpendicular to each other.

In an aspect, the invention also provides a method for fabricating photoelectric converting devices. A substrate is provided, and then a textured structure is formed on the substrate. The textured structure includes multiple repeated indented units. Each of the indented units has three planes in intersection, which form an indentation tip at the intersection point between the three planes. The three planes are perpendicular or about perpendicular to each other. An active layer is formed on the textured structure and is conformal to the textured structure.

In an aspect, the invention also provides a method for fabricating photoelectric converting device. A flat substrate is provided, and then an active layer is formed on the flat substrate. A textured structure is formed on the surface of the active layer. The textured structure includes multiple repeated indented units. Each of the indented units has three planes in intersection, which form an indentation tip at the intersection point between the three planes. The three planes are perpendicular or about perpendicular to each other.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a drawing which schematically illustrates the light reflection at a flat surface.

FIG. 2 is a drawing which schematically illustrates the light reflection for the inverted square pyramid texture.

FIG. 3 is a drawing which schematically illustrates a perspective structure of photoelectric converting device, according to an embodiment of the invention.

FIG. 4(a) is a top view of the structure in FIG. 3.

FIG. 4(b) is a cross-sectional view at the cutting line I-I in FIG. 4(a).

FIG. 5 is a drawing which schematically illustrates a light path for the incident light with three-time reflections for the textured structure.

FIG. 6 is a drawing which schematically illustrates the textured structure of the active layer, according to an embodiment of the invention.

FIGS. 7-9 are drawings which schematically illustrate the structures of the photoelectric converting device, according to embodiments of the invention.

FIG. 10 is a drawing which schematically illustrates a cross-sectional view of the photoelectric converting device, according to an embodiment of the invention.

FIG. 11 is a drawing which schematically illustrates a simulation result of absorption efficiency of the active layer with various textured structures thereon, respectively.

FIG. 12(a) is a drawing which schematically illustrates a top view of the photoelectric converting device as shown in FIG. 4(a).

FIG. 12(b) is drawing for one indented unit in FIG. 12(a) to show the distribution of regions with two and three reflections, respectively.

FIG. 13 is a drawing, schematically illustrating a model of the three planes for studying the variance of the angles.

FIG. 14 is a drawing, schematically illustrating the power absorbed by the Si film in theoretic study based on the model in FIG. 13.

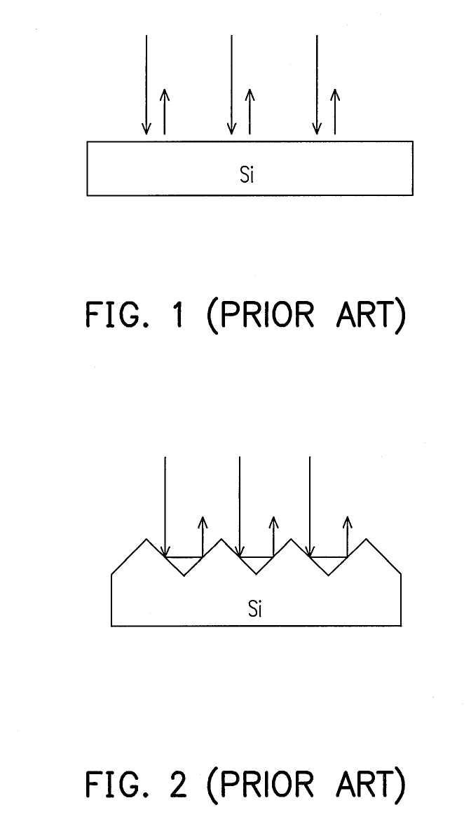

### DESCRIPTION OF THE PREFERRED EMBODIMENTS

Solar cell is a photoelectric converting device which converts the light energy into electric energy. The efficiency is usually affected by the internal quantum effect. In addition, it is crucially depends on whether or not the photons can effectively enter the active layer and be absorbed therein. Since the most semiconductor materials are high refractive index materials, the reflection occurring at the interface is typically high. If there is no proper light-in coupling structure, a lot of energy would be directly reflected without entering the semiconductor layer, causing waste of energy.

One approach to reduce the reflection loss is to design a structure which allows light to impinge on the interface many times. The invention proposes a corner cube structure. The corner cube structure has three planes perpendicular to each other to form an indented unit. As a result, the incident light is reflected trice and finally follows a direction parallel to the incident direction. The ratio of the light entering the device can be improved. If this structure is formed on a ceramic substrate, which behaves like a Lambertian surface, and thin film solar cell is coated thereon, then the light-in coupling efficiency of this solar cell can be better than those with inverted square pyramid structure.

Several embodiments are provided for description. However, the invention is not limited to the provided embodiments. And, the embodiment can also be properly combined with each other.

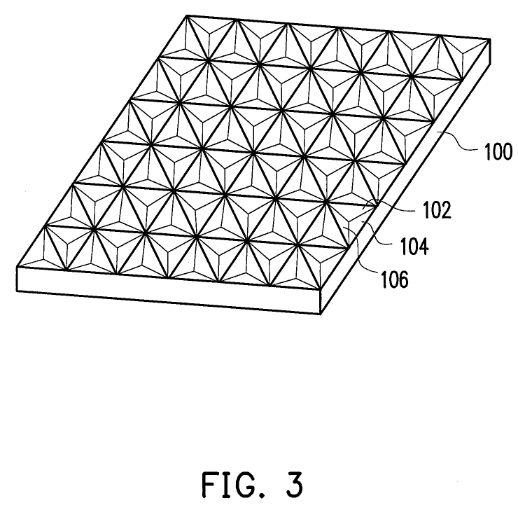

FIG. 3 is a drawing which schematically illustrates a perspective view of the photoelectric converting device, according to an embodiment of the invention. In FIG. 3, a textured structure is formed to increase the reflection number of times, such as to increase the probability of three-time reflections. The photoelectric converting device includes an active layer 100, for example. The active layer 100 has a textured structure. The textured structure includes multiple repeated indented units. Each of the indented units has three planes 102, 104, 106 in intersection, which form an indentation tip at the intersection point. The three planes 102, 104, 106 are perpendicular or about perpendicular to each other, allowing the light to be reflected multiply. As a result, the light can easily enter the active layer 11.

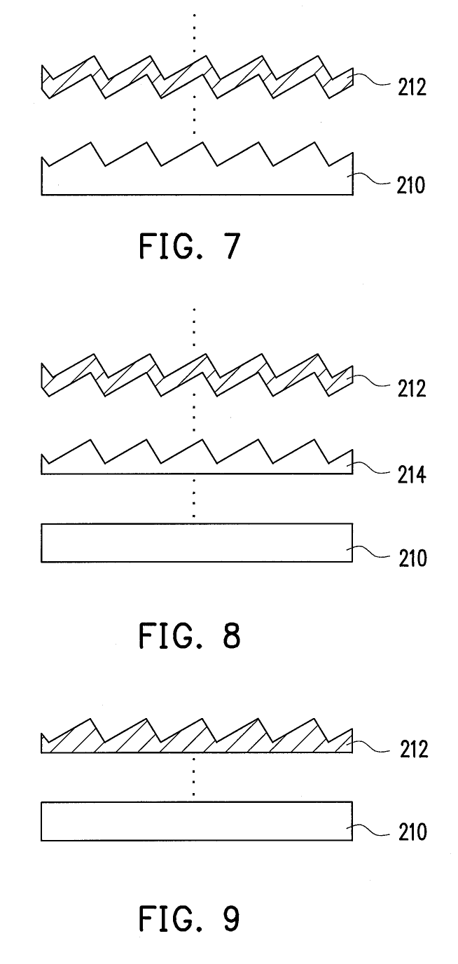

Further, the textured structure of the active layer 100 can be associated with the fabrication of the substrate, as described in FIGS. 7-9. The textured structure and the mechanism for reducing the reflection loss are described as follows.

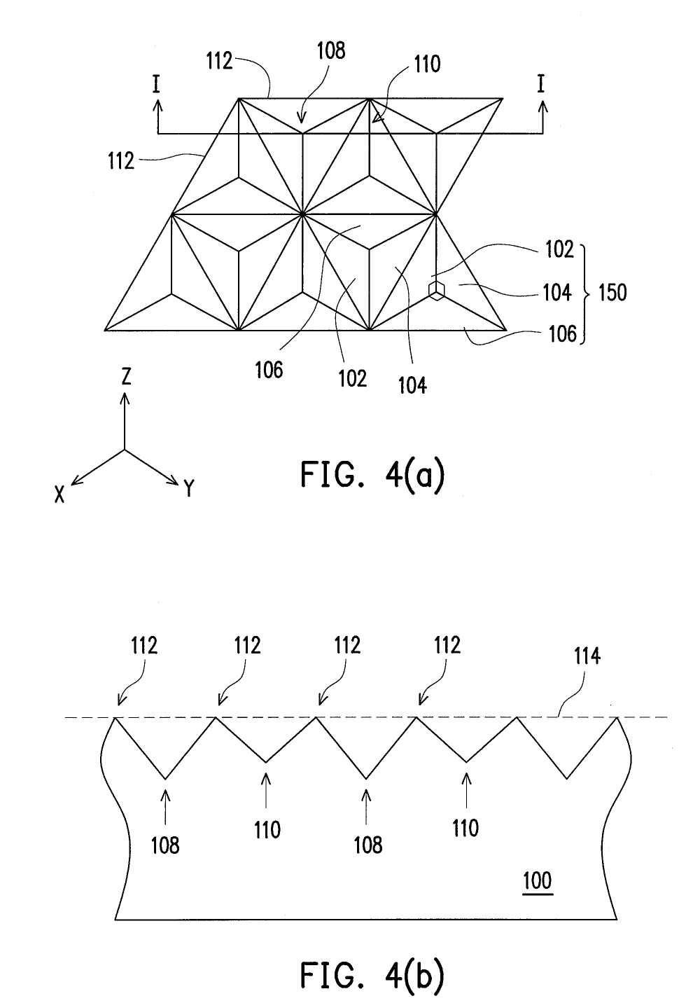

FIG. 4(a) is a top view of the structure in FIG. 3. FIG. 4(b) is a cross-sectional view at the cutting line I-I in FIG. 4(a). In FIG. 4(a) and FIG. 4(b), each indented unit 150 is formed by three planes 102, 104, and 106. The intersection lines 110 are like the axes of coordinate in XYZ. The indentation tip 108 can be considered the origin of the coordinate. The side lines 112 of each indented unit 150 are distributed on a plane. In this embodiment, the textured structure is directly formed on the light-receiving surface of the active layer 100.

In this embodiment, multiple repeated indented units 150 can be configured to a triangle arrangement. Each indented unit 150 is a regular triangle when viewing on top of the photoelectric converting device. Each regular triangle is adjacent, to one another in a most compact manner to cover the whole surface. In this configuration, if only the texture is considered, most of the vertically incident light would be reflected thrice.

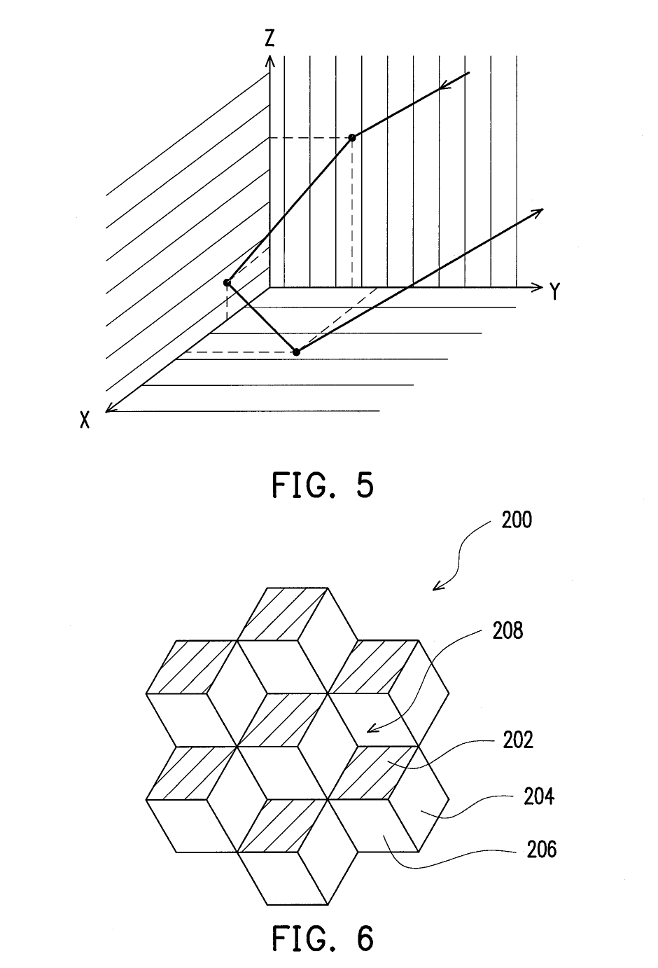

FIG. 5 is a drawing which schematically illustrates the light path of the light impinging on an indented unit of the textured structure. Since the three planes are perpendicular to each other, the light will be reflected by each plane once. In FIG. 5, xy plane, yz plane, and xz plane are perpendicular to each other. The incident light, as shown by the arrow, is reflected by each plane once, and leaves along the direction parallel to the incident direction. The three planes perpendicular to each other comprise an indented unit, and multiple indented units form an array. If the indented units are properly arranged, and only the textured structure is taken into consideration, most of the right will be reflected thrice. Therefore, the invention proposes a textured structure which can improve the light-in coupling efficiency for the solar cell. The reflection loss at the interface can be reduced down to about 4%, for example.

Here, the three planes in preferred arrangement are perpendicular to each other. In this preferred arrangement, the light-in coupling efficiency is sufficiently good without adopting high aspect-ratio structures. However, if the three planes are about perpendicular to each other, the texture structure still has reasonable light-in coupling improvement. More specifically, if the angles between any two normal directions of the three planes are between 60 and 120 degree, this textured structure still works well.

FIG. 6 is a drawing which schematically illustrates the textured structure of the active layer, according to an embodiment of the invention. In FIG. 6, the indented unit of the textured structure 200 of the active layer is composed of, for example, three planes 202, 204, and 206 in normal intersection. The common intersection point is the indentation tip 208. In the top view, each indented unit has a regular hexagonal perimeter. In this arrangement, if only the textured structure is considered, 100% of incident light experiences three reflections.

In addition, the size of the indented unit can be adjusted according to the actual need. As long as the size of the indented unit is much larger than the wavelength of incident light, it has negligible influence.

As for fabrication, in order to have the textured structure on the active layer, there are several fabrication processes, resulting in different stack structures. FIG. 7 is a drawing, schematically illustrating the structures of the photoelectric converting device, according to an embodiment of the invention. In FIG. 7, the textured structure of the invention can be first formed on a substrate 210. The process can be, for example, hot isostatic pressing, hot rolling, laser, or photolithography. The indented units arranged as an array are formed on the substrate 210 of the photoelectric converting device. Then, functional layers can be coated cover over the substrate 210. The functional layers include an active layer 212. Thus, the functional layers with the active layer 212 follow the same textured structure as that on the substrate 210. Therefore, the light receiving surface of the active layer 212 can have the same textured structure.

In addition to FIG. 7, another fabrication process can be taken. FIG. 8 is drawing schematically illustrating the structures of the photoelectric converting device, according to an embodiment of the invention. In FIG. 8, the substrate 210 can have a flat plane. By the fabrication processes such as thermal forming or optical forming, the structure is formed on an interlayer 214 between the active layer and the substrate. The interlayer 214 has the textured structure. By coating or other method, the other functional layers, including the active layer 212, cover thereon, so that the functional layers with the active layer 212 can reproduce the textured structure. As a result, the active layer 212 also has the textured structure.

Another fabrication method is, for example, shown in FIG. 9. FIG. 9 is drawing which schematically illustrates the structures of the photoelectric converting device, according to an embodiment of the invention. In FIG. 9, with additional one or more layer on the substrate 210 and making use of the fabrication processes mentioned above, the textured structure can be directly formed on an interface of the active layer 212.

In other words, a surface of the active layer 212 for receiving light needs to be formed with the textured structure. However, for a stack structure, the fabrication process is not limited to a specific process flow.

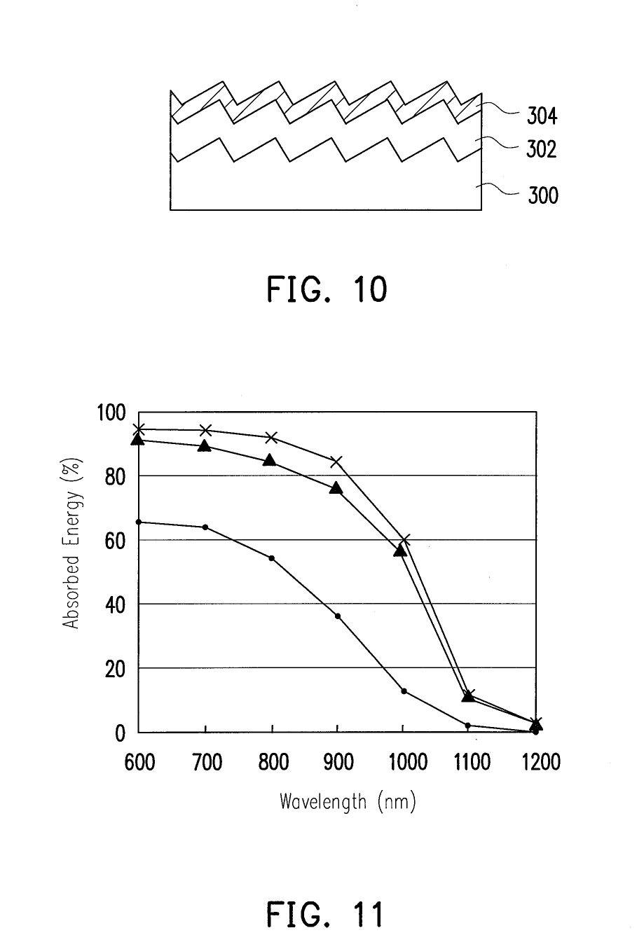

FIG. 10 is a drawing which schematically illustrates a cross-sectional view of the photoelectric converting device with high light-in coupling efficiency, according to an embodiment of the invention. In FIG. 10, an embodiment of the photoelectric converting device includes a ceramic substrate 300. The corner cube structure proposed by the invention is transferred from a mold to the substrate. The ceramic substrate 300 is deposited with a conformal layer 302, such as silicon oxide layer. Its thickness is, for example, 100 microns. The active layer 304 is made of single-crystal silicon with thickness of, for example, 5 microns. It is deposited on the conformal layer 302, and reproduces the same textured structure. Therefore, the substrate 300, the conformal layer 302, and the active layer 304 all have the same textured structure on them. The textured structure contains multiple indented units. Each of the indented unit includes three planes perpendicular to each other. In the top view, the perimeter of each indented unit forms a regular triangle with 20 microns side length. The triangles are arranged in a most compact manner to cover the whole surface.

FIG. 11 is a drawing which schematically illustrates the simulated absorption efficiencies for solar cells with the same materials but different textured structures. The absorption efficiency is defined as the ratio of the energy absorbed by the active layer to overall incident energy. In FIG. 11, the round dotted curve represents the simulated absorption efficiency versus wavelength for a solar cell without any light-in coupling structure. The triangle dotted curve represents the simulated absorption efficiency versus wavelength for a solar cell whose active layer has inverted square pyramid structure on it. The crossing dotted curve represents the simulated absorption efficiency versus wavelength for a solar cell possessing the textured structure showed by FIG. 10.

Observing the results in FIG. 11, the corner cube structure proposed by the invention is indeed helpful to increase light absorption and reduce reflection loss. The reason is that the invention can increase the number of reflections, and therefore allows the incident light to have more chance to enter the active layer to be absorbed.

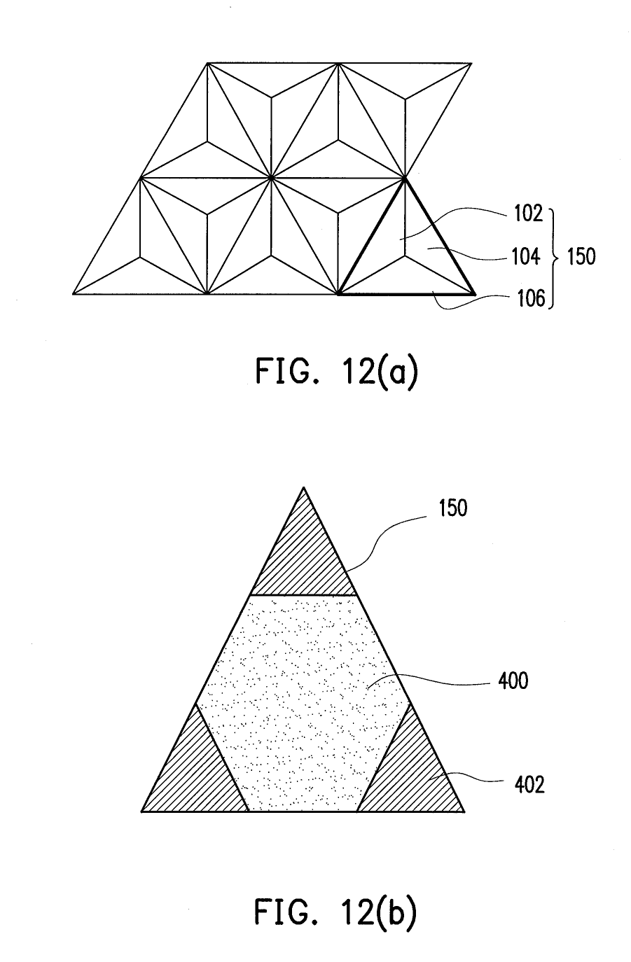

FIG. 12(a) is a drawing, which schematically illustrates the top view of the photoelectric converting device showed by FIG. 4(a). In FIG. 12(a), an indented unit 150 defined by the thick line is simulated by conducting light tracing. In FIG. 12(b), regions with two-time reaction and three-time reflections are showed respectively. If light is incident on region 400, it would experience three reflections by all three planes. On the other hand, the light impinging region 402 would experience two reflections before leaving the structure. With more reflections, the active layer has more chance to absorb the light. Therefore, the light impinging region 400 is more probable to be absorbed than that impinging region 402.

Further, the incident light, normal to the substrate layer, is actually not normally incident to the indented planes 102, 104, 106. In other words, the incident angle is not zero. Considering the reflection on air/silicon interface, theoretical data show that when the light is non-polarized, the reflectivity is about the same for all angles below 60 degree. If the incident angle is greater than 60 degrees, the reflectivity increases dramatically. When light impinges the device in the direction normal to the substrate, the incident angles with respect to indented planes 102, 104, and 106 are less than 60 degrees. Therefore, the textured structure of the invention would not increase the reflectivity of each single reflection.

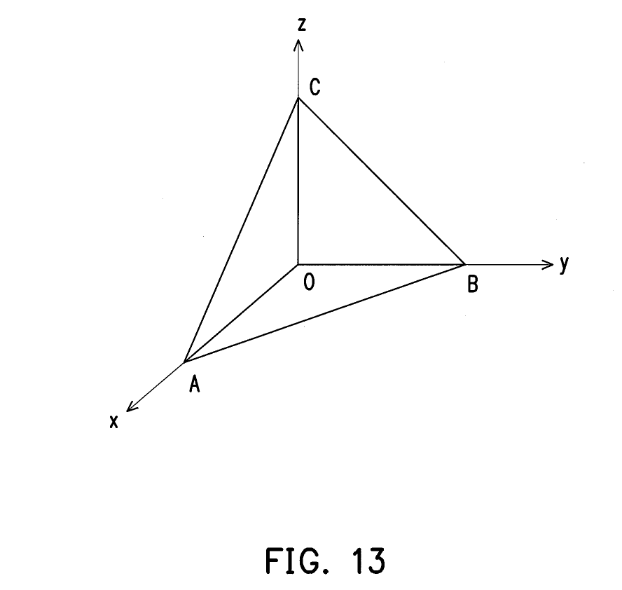

For the further study in varying the angles between the three planes, without limiting to the perpendicularity between the three planes, a theoretic study has been made. FIG. 13 is a drawing, schematically illustrating a model of the three planes for studying the variance of the angles. Taking the model as shown in FIG. 13, some parameters are defined as follows. In an xyz coordinate system, for an ideal geometry, the tip of the corner cube is located at the origin point O. If the tip is moving along the direction of a vector [1,1,1], the angle phi, defined by phi=∠AOB=∠BOC=∠AOC, is no longer 90 degrees. Also, an angle theta is defined by the included angle of normal directions of any two of planes AOB, AOC, and BOC.

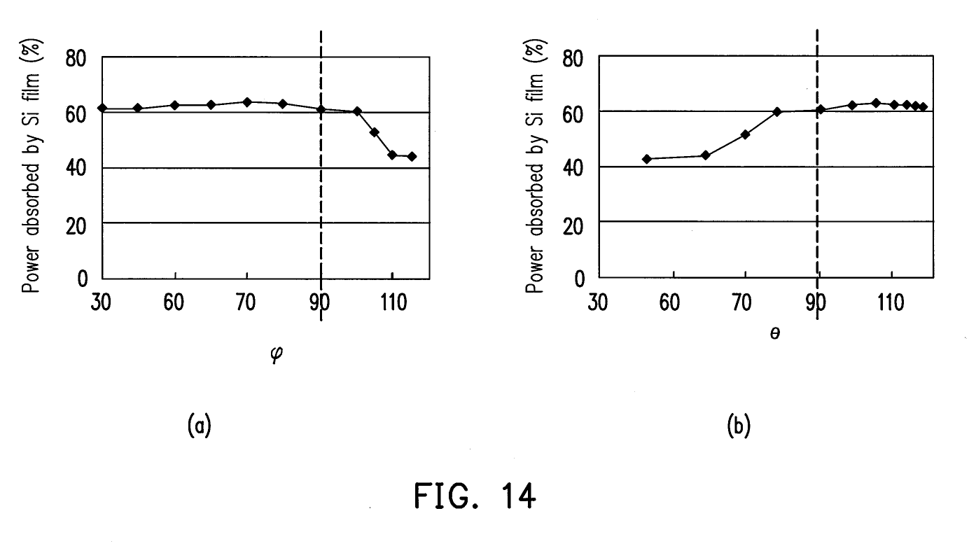

FIG. 14 is a drawing, schematically illustrating the power absorbed by the Si film in theoretic study based on the model in FIG. 13. In FIG. 14, the power absorbed by the Si film is studied. As shown in FIG. 14 (b), the power absorbed by the Si film dramatically increases as the angle theta is greater than 60 degrees, and becomes stable as the angle theta is greater than 90 degrees. Therefore, this structure effectively improves the light-in coupling and light trapping if the angle theta is within a range near 90 degrees, say, about 60°-120°. It is preferable to choose 90 degrees because further increasing the angle theta doesn't improve much but increases the difficulty to produce this structure. Likewise, as shown by FIG. 14(a), the angle phi can also be within a range near 90 degrees and this device still works well.

The invention uses the corner cube as the indented unit, which results in multiple reflections, so that the absorption efficiency can effectively increase.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A photoelectric converting device, comprising:
a substrate layer; and
an active layer, disposed over the substrate layer, the active layer has a light receiving surface with a textured structure,
wherein the textured structure comprises multiple repeated indented units and each of the indented units comprises intersecting three planes, which form an indentation tip at an intersection point between the three planes, and the three planes are perpendicular or about perpendicular to each other.

2. The photoelectric converting device of claim 1, wherein the substrate layer and the active layer form a solar cell or an optical sensor.

3. The photoelectric converting device of claim 2, wherein the solar cell includes a material of amorphous silicon, polysilicon, crystal silicon, silicon/germanium, III-V or II-VI semiconductor, small organic molecule, polymer, dye sensitized material, or copper indium gallium selenide (CIGS).

4. The photoelectric converting device of claim 1, wherein each of the indented units is an inverted triangular pyramid.

5. The photoelectric converting device of claim 1, wherein the three planes of each of the indented units are formed from three intersecting planes being cubic.

6. The photoelectric converting device of claim 1, wherein each of the indented units in the top view is a triangle or a hexagon.

7. The photoelectric converting device of claim 1, wherein the substrate has a textured structure, and the active layer is same in shape with the textured structure.

8. The photoelectric converting device of claim 1, wherein the substrate layer comprises:
a flat base layer; and
an interlayer, disposed on the flat base layer, having a textured structure,
wherein the active layer is same in shape with the textured structure.

9. The photoelectric converting device of claim 1, wherein the substrate layer is a flat base layer, and the active layer has a flat back surface, disposed on the flat base layer.

10. A method for fabricating photoelectric converting device, comprising:
providing a substrate layer; and
forming a textured structure on the substrate layer, wherein the textured structure comprises multiple repeated indented units, each of the indented units has three planes in intersection, which form an indent tip at an intersection point between the three planes; the three planes are perpendicular or about perpendicular to each other; and
forming an active layer on the textured structure, wherein the active layer has a same shape of the textured structure.

11. The method of claim 10, wherein each of the indented units is formed as an inverted triangular pyramid.

12. The method of claim 10, wherein each of the indented units is formed from three intersecting planes of a cube.

13. The method of claim 10, wherein the textured structure is directly formed on the substrate layer.

14. The method of claim 10, wherein the process of forming the textured structure on the substrate layer comprises:
providing a flat base layer;
disposing an interlayer on the flat base layer; and
forming a surface structure on the interlayer.

15. A method for fabricating photoelectric converting device, comprising:
providing a flat substrate;
forming an active layer on the flat substrate; and
forming a textured structure on the active layer, wherein the textured structure comprises multiple repeated indented units, each of the indented units has three planes in intersection, which form an indentation tip at an intersection point between the three planes; the three planes are perpendicular or about perpendicular to each other.

16. The method of claim 15, wherein the three planes of each of the indented units form an inverted triangular pyramid or form a cube by intersection.
